(19) United States
(12) Patent Application Publication
(10) Pub. No.: US 2013/0152703 A1
(43) Pub. Date: Jun. 20, 2013

(54) MAGNETOSTRICTIVE TORQUE SENSOR AND METHOD OF MANUFACTURING THE SAME

(71) Applicant: HONDA MOTOR CO., LTD., Tokyo (JP)

(72) Inventors: Yutaka ARIMURA, SAITAMA (JP); Yasuo SHIMIZU, SAITAMA (JP); Atsuhiko YONEDA, SAITAMA (JP)

(73) Assignee: HONDA MOTOR CO., LTD., TOKYO (JP)

(21) Appl. No.: 13/713,441

(22) Filed: Dec. 13, 2012

(30) Foreign Application Priority Data
Dec. 14, 2011 (JP) 2011-273181

(51) Int. Cl. G01L 3/10; G01R 3/00

(52) U.S. Cl. CPC G01L 3/102; G01R 3/00
USPC 73/862.333; 29/602.1

(57) ABSTRACT

A magnetostrictive torque sensor includes a housing configured to house a magnetostrictive element provided on a rotary shaft, a single coil bobbin and detection coils wound on the coil bobbin. The housing includes a plastic housing body having a generally cylindrical shape and molded integrally with the coil bobbin having the detection coils wound thereon, a metal flange portion disposed on an axial end portion of the generally cylindrical plastic housing body, and a plastic fastener member firmly connecting the metal flange portion to the axial end portion of the plastic housing body. A method of manufacturing such torque sensor is also disclosed.

### FIELD OF THE INVENTION

The present invention relates to a magnetostrictive torque sensor and a method of manufacturing such magnetostrictive torque sensor.

### BACKGROUND OF THE INVENTION

Magnetostrictive torque sensors are employed in, for example, an electric power steering apparatus for motor vehicles. A typical example of such magnetostrictive torque sensors is disclosed in Japanese Patent Application Laid-open Publication (JP-A) No. 2007-292727, corresponding to U.S. Pat. No. 8,225,483.

The magnetostrictive torque sensor disclosed in JP 2007-292727A includes a magnetostrictive element provided on a rotary shaft, first and second coil units mounted to surround the magnetostrictive element, and a housing accommodating therewithin the magnetostrictive material and the coil units. The housing has an end flange for connection to another case member. The housing including the end flange is molded of synthetic resin. The coil units are supported by the housing as they are molded integrally with the housing.

In the manufacture of the disclosed magnetostrictive torque sensor, first and second coil units are fitted onto a cylindrical centering rod in tandem relation to each other. Then, a molding die assembly is set to enclose the coil units such that a mold cavity which is complementary in contour to a housing to be produced is defined within the molding die assembly. A molten resin is injected into the mold cavity, so that a plastic housing is produced with an end flange formed integrally with a housing body and with the coil units molded integrally with the housing body. Since the molding process is carried out while the coil units are fitted onto the centering rod, the coil units and the housing are concentric with each other.

In the molding process, the molten resin injected into the mold cavity undergoes thermal contraction as it cools down and becomes solidified. The amount of thermal contraction increases with an increase in the amount of synthetic resin material used. The end flange of the housing, which is adapted to be connected to another case member, requires a high mechanical strength and hence is made thicker than other parts of the housing. This means that due to a relatively large amount of synthetic resin material used, the end flange may undergo relatively large thermal contraction during injection molding process. When such thermal contraction occurs, a relatively large compressive force is applied to a part of one coil unit which is located adjacent to the end flange. This will deteriorate the sensing accuracy of the coil units because the coil units operate as a member for detecting variations in magnetic property of the magnetostrictive element.

### SUMMARY OF THE INVENTION

It is, therefore, an object of the present invention to provide a magnetostrictive torque sensor having high detection accuracy and a method of manufacturing such magnetostrictive torque sensor.

According to a first aspect of the present invention, there is provided a magnetostrictive sensor comprising: a rotary shaft; a magnetostrictive element provided on the rotary shaft; a single coil bobbin arranged to face the magnetostrictive element; a plurality of detection coils wound on the coil bobbin and spaced apart in an axial direction of the coil bobbin for detecting a change in magnetic characteristic of the magnetostrictive element; and a housing configured to house the magnetostrictive element, the coil bobbin and the detection coils, wherein the housing includes a plastic housing body having a generally cylindrical shape and molded integrally with the coil bobbin with the detection coils wound on the coil bobbin, a metal flange portion disposed on an axial end portion of the generally cylindrical plastic housing body, and a plastic fastener member firmly connecting the metal flange portion to the axial end portion of the plastic housing body.

With this arrangement, since the housing body and the flange portion are formed of different materials and structurally independent from each other, and since the plastic housing body is molded integrally with the coil bobbin with the detection coils wound on the coil bobbin, the housing body can be formed into a generally cylindrical shape having a uniform thickness throughout an axial length thereof. This means that the amount of thermal contraction occurring when the plastic housing body is formed by molding is substantially uniform with respect to the detection coils, which will insure highly accurate detection accuracy of the magnetostrictive torque sensor. Additionally, integral formation of the housing body and the coil bobbin having the detection coils wound thereon can obviate the need for screws and a collar that are conventionally used for mounting the coil bobbin and the detection coils in the housing body.

In one preferred form of the invention, the axial end portion of the plastic housing body has a cylindrical surface and a circumferential groove formed in the cylindrical surface, the metal flange portion has a central boss fitted with the cylindrical surface of the axial end portion of the plastic housing body and a plurality of through-holes extending radially through the central boss, the through-holes having one end connected with the circumferential groove of the axial end portion of the plastic housing body, and the plastic fastener member has a first ring-shaped portion disposed on a radial outer side of the central boss of the metal flange portion, a second ring-shaped portion disposed in the circumferential groove of the axial end portion of the plastic housing body and a plurality of radial arms extending between the first and second ring-shaped portions and disposed in respective ones of the through-holes of the metal flange portion. By virtue of the radial arms disposed in the through-holes of the metal housing portion, the plastic fastener member is locked in position against rotation relative to the metal flange portion and the plastic housing member.

Preferably, the plastic fastener member is molded integrally with the plastic housing body and the metal flange portion. The molded plastic fastener member undergoes thermal contraction as it cools down and becomes solidified during a molding process. However, the thermal contraction of the fastener element gives no direct effect on the detection coils and, hence, the magnetostrictive torque sensor can retain a good temperature characteristic.

The magnetostrictive torque sensor may further comprise an elastic member disposed between the axial end portion of the plastic housing body and the metal flange portion in an elastically distorted condition such that an elastic restoring force of the elastic member acts in a direction to urge the plastic housing body and the metal flange portion to move away from each other along an axis of the rotary shaft. This arrangement ensures that when the magnetostrictive torque sensor is subjected to heat, the plastic housing body, which has a larger linear expansion coefficient than the metal flange portion, is allowed to move relative to the metal flange portion in an axial direction of the rotary shaft so as to follow thermal expansion of the rotary shaft on which the magnetostrictive element is provided. Thus, the torque sensor can retain good temperature characteristic.

Preferably, the axial end portion of the plastic housing body has an end surface disposed in abutting contact with a surface of the metal flange portion and an annular groove formed in the end surface, and the elastic member is an O-ring disposed in the annular groove of the plastic housing body. The annular groove can readily be formed when the plastic housing body is formed by molding.

According to a second aspect of the present invention, there is provided a method of manufacturing a magnetostrictive torque sensor including a housing having a plastic housing body and a metal flange portion firmly connected to an end portion of the plastic housing body by a plastic fastener member with a coil bobbin firmly held within the plastic housing body with a plurality of detection coils wound on the coil bobbin, the method comprising the steps of providing a single coil bobbin having a plurality of detection coils wound thereon, and a metal flange portion; setting the coil bobbin in a first molding die assembly such that a mold cavity which is complementary in contour to the plastic housing body of the housing to be produced is formed within the first molding die assembly; filling the mold cavity with a molten synthetic resin material to thereby form a plastic housing body having the coil bobbin firmly held therein with the detection coils wound on the coil bobbin; setting the plastic housing body and the metal flange portion in a second molding die assembly such that a mold cavity which is complementary in contour to the plastic fastener member of the housing to be produced is formed within the second molding die assembly; and filling the mold cavity of the second molding die assembly with a molten synthetic resin material to thereby obtain a housing having the metal flange portion firmly connected to an axial end portion of the plastic housing body by a molded plastic fastener member.

Since the plastic housing body is formed integrally with the coil bobbin having the detection coils wound thereon in a first or primary molding process before it is joined with the metal flange portion, it is possible to form the plastic housing body into a generally cylindrical shape having a substantially uniform thickness throughout an axial length thereof. The cylindrical plastic housing body with uniform thickness, as it cools down and becomes solidified during the molding process, may undergo thermal contraction occurring uniformly throughout the axial length of the housing body. This will ensure that an air-gap between the coil bobbin and the magnetostrictive element on the rotary shaft remains constant with respect to each of the detection coil elements. The detection coils can retain high detection accuracy. Furthermore, since the metal flange portion is firmly connected to the axial end portion of the plastic housing body by the plastic fastener member molded in a secondary molding process, thermal contraction of the molded fastener member gives no direct effect on the performance of the detection coils. Thus, highly accurate detection sensitivity of the detection coils can be maintained.

It is preferable that the setting the plastic housing body and the metal flange portion in the second molding die assembly is carried out while an elastic member is held between the axial end portion of the plastic housing body and the metal flange portion in an elastically distorted condition such that an elastic restoring force of the elastic member acts in a direction to urge the plastic housing body and the metal flange portion to move away from each other along an axis of the plastic housing body.

### BRIEF DESCRIPTION OF THE DRAWINGS

Certain preferred structural embodiments of the present invention will be described in detail herein below, by way of example only, with reference to the accompanying sheets of drawings, in which:

FIG. 1 is a diagrammatical view of an electric power steering apparatus in which a magnetostrictive torque sensor according to the present invention is incorporated:

FIG. 2 is a front elevational view, with parts cut away for clarity, of the electric power steering apparatus shown in FIG. 1;

FIG. 3 is a cross-sectional view taken along line 3-3 of FIG. 2;

FIG. 4 is a perspective view of a flange portion before being molded with the body of a housing of the magnetostrictive torque sensor;

FIG. 5 is an exploded perspective view showing structural components of the housing;

FIG. 6A is a cross-sectional view illustrative of the manner in which a coil bobbin is set on a first molding die member in a primary molding process;

FIG. 6B is a cross-sectional view showing the manner in which a mold cavity is defined within a molding die assembly in the primary molding process;

FIG. 7A is a cross-sectional view showing the manner in which the mold cavity in the molding die assembly is filled with a molten synthetic resin material in the primary molding process;

FIG. 7B is a cross-sectional view showing a molded product produced by the primary molding process;

FIG. 8A is a cross-sectional view illustrative of the manner in which the molded product and the flange portion are set on a first molding member in a secondary molding process;

FIG. 8B is a cross-sectional view showing the manner in which a mold cavity is defined within a molding die assembly in the secondary molding process;

FIG. 9 is a cross-sectional view illustrative of the manner in which the mold cavity in the molding die assembly is filled with a molten synthetic resin material in the secondary molding process; and

FIG. 10 is a cross-sectional view of a magnetostrictive torque sensor according to a second embodiment of the present invention.

### DESCRIPTION OF THE PREFERRED EMBODIMENTS

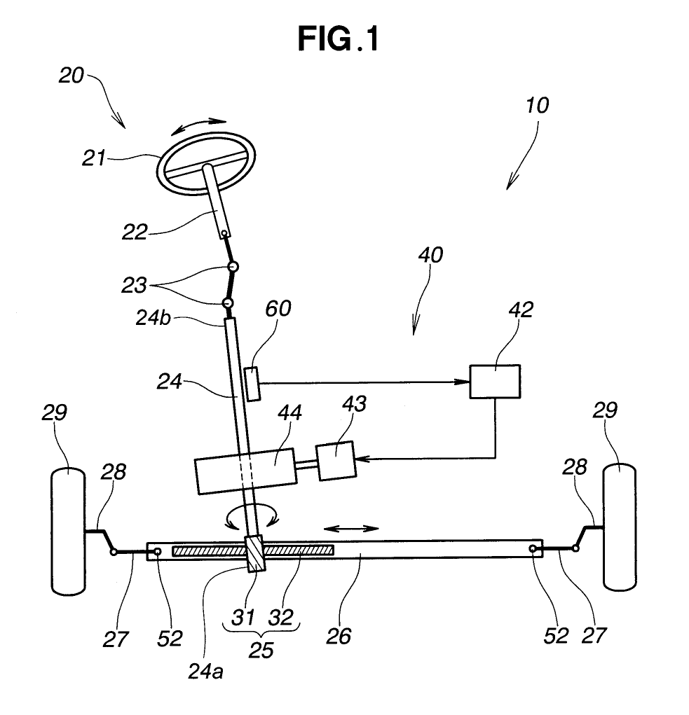

Referring now to the drawings and FIG. 1 in particular, there is shown in diagrammatical view an electric power steering apparatus 10 of a vehicle in which a magnetostrictive torque sensor embodying the present invention is incorporated.

The electric power steering apparatus 10 shown in FIG. 1 generally comprises a steering system 20 extending from a vehicle steering wheel 21 to steerable road wheels (in the illustrated embodiment, right and left front road wheels) 29 of the vehicle, and a steering torque assist mechanism 40 for supplying steering assist torque to the steering system 20.

In the steering system 20, a pinion shaft (input shaft) 24 is coupled to the steering wheel 21 via a steering shaft 22 and universal joints 23, and a rack shaft 26 is coupled to the pinion shaft 24 via a rack-and-pinion mechanism 25. Further, the right and left steerable road wheels 29 are coupled to opposite ends of the rack shaft 26 via right and left tie rods 27 and knuckle arms 28. The rack-and-pinion mechanism 25 includes a pinion 31 formed on the pinion shaft 24 and a rack 32 formed on the rack shaft 26.

With the steering system 20 thus arranged, when a human operator or driver of the vehicle operates the steering wheel 21, steering torque is delivered from the steering wheel 21 to the right and left steerable road wheels 29 via the rack-and-pinion mechanism 25, right and left tie rods 27 etc. and thereby steers the road wheels 29.

The steering torque assist mechanism 40 includes a magnetostrictive torque sensor 60 for detecting steering torque applied by the driver to the steering system 20 through operation of the steering wheel 21, a control unit 42 for generating a control signal on the basis of a torque detection signal from the magnetostrictive torque sensor 60, an electric motor 43 for generating steering assist torque corresponding to the driver-applied steering torque on the basis of the control signal, and a worm gear mechanism 44 for transmitting the motor-generated steering assist torque from the motor 43 to the pinion shaft 24. The steering assist torque transmitted to the pinion shaft 24 is further transmitted to the rack-and-pinion mechanism 25.

With the steering torque assist mechanism 40 thus arranged, the right and left steerable road wheels 29 are steered by a combination of (i.e., composite torque composed of) the driver-applied steering torque and motor-generated steering assist torque via the rack shaft 26.

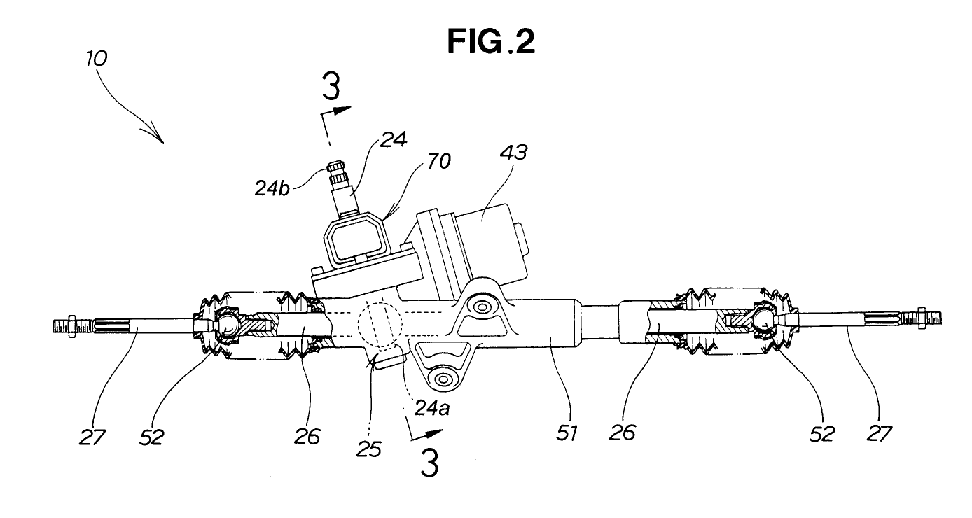

FIG. 2 shows the general configuration of the electric power steering apparatus 10 with parts cut away for clarity. As shown in this figure, the rack shaft 26 is accommodated in a lower housing 51 extending in a widthwise direction of the vehicle (right-and-left direction in FIG. 2), and the rack shaft 26 is slidable axially within the lower housing 51. The tie rods 27, 27 are coupled, via ball joints 52, 52, to the opposite ends of the rack shaft 26 projecting outwardly from the lower housing 51.

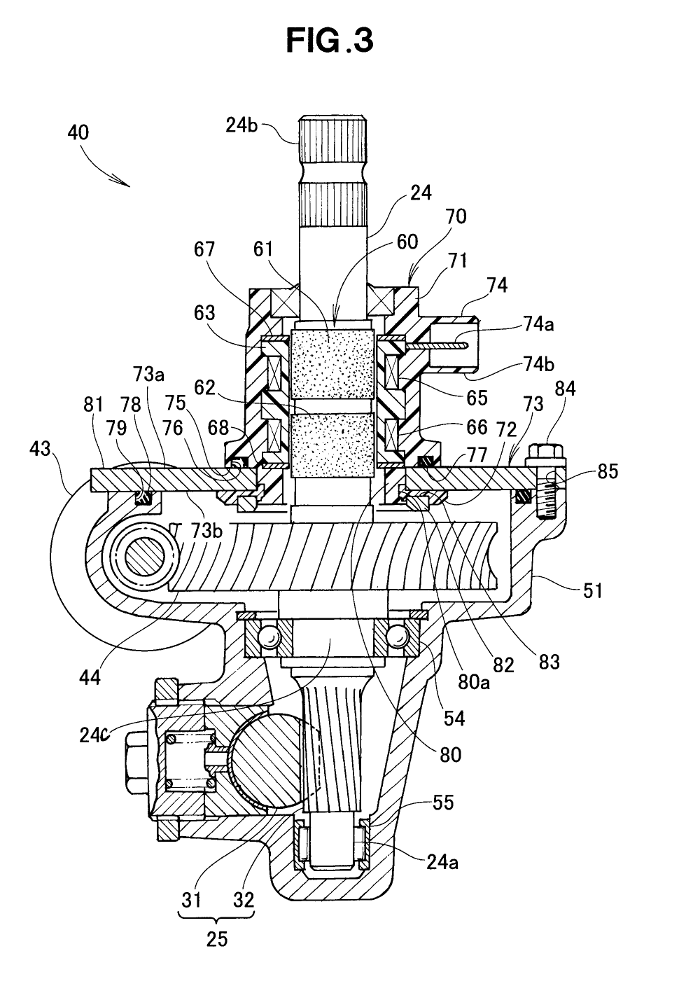

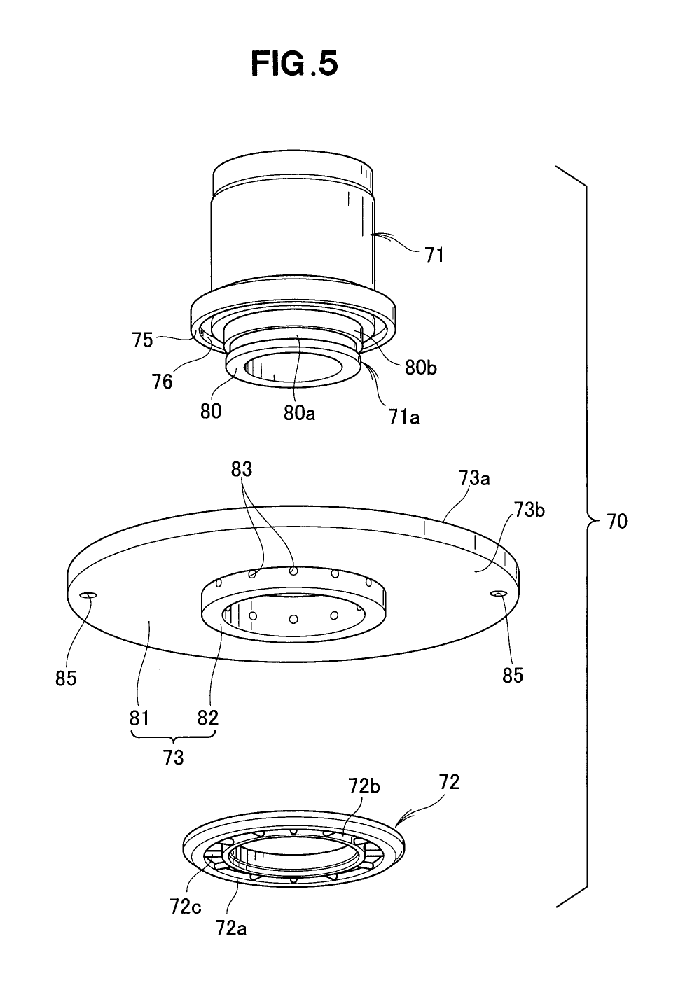

As shown in FIG. 3, the magnetostrictive torque sensor 60 is comprised of first and second magnetostrictive elements 61 and 62 provided on an outer circumferential surface of the pinion shaft 24 and each having a magnetostrictive characteristic which is variable with torque, a single coil bobbin 63 arranged to face or surround the magnetostrictive elements 61, 62, first and second detection coils 65 and 66 wound on the coil bobbin 63 and spaced apart in an axial direction of the coil bobbin 63 for detecting a magnetostriction effect generated by the magnetostrictive elements 61, 62, yokes 67, 68 disposed on opposite end faces of the coil bobbin 63, a plastic housing body 71 firmly holding the yokes 67, 68 and the coil bobbin 63 as a single unit with the detection coils 65, 66 wound on the coil bobbin 63, a metal flange portion 73 firmly connected to an end portion 71a (FIG. 5) of the housing body 71 via a plastic fastener member 72, and a terminal 74 formed integrally with the plastic housing body 71. The plastic housing body 71 and the metal flange portion 73 that are connected together by the plastic fastener member 72 form an upper housing 70. The upper housing 70 is bolted to the lower housing 51 at the flange portion 73 thereof. The upper housing 70 solely forms a housing of the magnetostrictive torque sensor 60.

The magnetostrictive elements 61, 62 are magnetostrictive films formed on the outer circumferential surface of the pinion shaft 24 and having a residual strain in opposite directions along a longitudinal axis of the pinion shaft 24. The magnetostrictive films 61, 62 are formed of a material which can create a magnetic flux density variable greatly with a change in distortion. The magnetostrictive elements 61, 62 may have a magnetic anisotropy in opposite directions to each other and, hence, they can be formed by a single magnetostrictive film having two magnetostrictive parts or regions separated in the axial direction of the pinion shaft 24.

The housing body 71 has a generally cylindrical shape and is connected at the lower axial end portion 71a (FIG. 5) to the flange portion 73 by the plastic fastener member 72. The lower end portion 71a of the housing body 71 has a lower end surface 75 disposed in abutting contact with an upper surface 73a of the metal flange portion 73, and an annular groove 76 formed in the lower end surface 75. An elastic seal member 77 such as an O-ring is received in the annular groove 76 in an elastically deformed or distorted condition so that a hermetic seal is formed between the lower end face 75 of the housing body 71 and the upper surface 73a of the flange portion 73. With the elastic seal member 77 thus disposed in an elastically deformed or distorted condition within the annular groove 76, an elastic restoring force of the distorted elastic seal member 77 normally acts in a direction to urge the housing body 71 and the flange portion 73 to separate relatively from each other along an axis of the rotary shaft 24.

As better shown in FIG. 5, the lower end portion 71a of the housing body 71 also has a central boss 80 projecting downwards from the lower end face 75, and a circumferential groove 80a formed in an outer cylindrical surface 80b of the central boss 80 for a purpose described later.

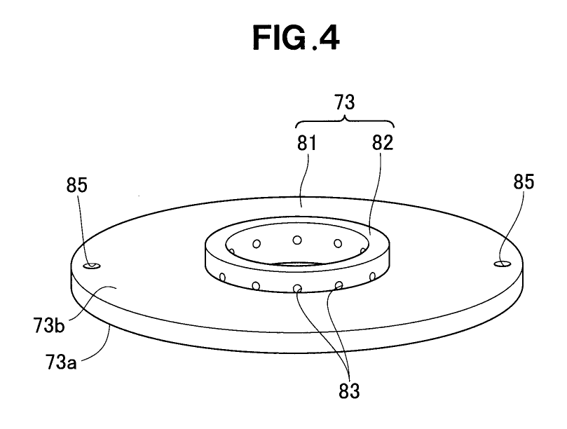

As shown in FIGS. 4 and 5, the flange portion 73 of the upper housing 70 (FIG. 3) is in the form of a circular disk having a flat web section 81 and a central boss 82 projecting from one surface 73b (lower surface in FIG. 3) of the web section 81. The boss 82 has a plurality (twelve in the illustrated embodiment) of radial through-holes 83 formed therein and spaced at regular intervals in a circumferential direction of the boss 82. The through-holes 83 are connected at one end (inner end) to the circumferential groove 80a (FIG. 3) of the boss 80 of the housing body 71. The flange portion 73 also has a pair of holes 85 formed in an outer peripheral portion of the web section 81 for the passage therethrough of a pair of bolts 84 (one being shown in FIG. 3), respectively.

The plastic fastener member 72 is configured to extend between a radial outward side of the central boss 82 of the flange portion 73 and an internal space of the circumferential groove 80a of the boss 85 of the housing body 71 through the radial through-holes 83 of the flange portion 73. More specifically, as shown in FIG. 5, the plastic fastener member 72 has a disk-like configuration and includes an outer ring-shaped portion 72a, an inner ring-shaped portion 72b and a plurality of radial arms 72c extending between the outer and inner ring-shaped portions 72a and 72b. As shown in FIG. 3, the outer ring-shaped portion 72a is disposed on the radial outer side of the boss 82 of the metal flange portion 73, the inner ring-shaped portion 72b is disposed in the circumferential groove 80a of the boss 80 of the housing body 71, and the radial arms 72c are disposed in respective ones of the through-holes 83 of the flange portion 73. The circumferential groove 80a is filled with the material of the inner ring-shaped portion 72b, and the through-holes 83 are filled with the material of the radial arms 72c. By the plastic fastener member 72 thus constructed, the housing body 71 and the flange portion 73 are firmly connected together at the lower end portion 71a (FIG. 5) of the housing body 71. By virtue of the radial arms 72c disposed in the through-holes 83 of the metal flange portion 73, the plastic fastener member 72 is locked in position against rotation relative to the metal flange portion 73 and the plastic housing body 71.

The pinion shaft 24 is rotatably supported by the lower housing 51 via a pair of bearings 54 and 55 at a longitudinally intermediate portion 24c and an output end portion 24a (lower end portion in FIG. 3) that are located below the flange portion 73 of the upper housing 70. Another longitudinally intermediate portion of the pinion shaft 24 which is located above magnetostrictive element 61 is rotatably supported by the upper housing 70 via a seal member (not designated) mounted in an upper end portion of the housing body 71.

The plastic housing body 71 has a larger linear expansion coefficient than the metal flange portion 73. The plastic housing body 71 and the plastic fastener member 72 may be formed of a same synthetic resin material.

The lower housing 51 has an annular groove 79 formed in an upper end face thereof, and an elastic seal member 78 such as an O-ring is disposed in the annular groove 79. The flange portion 73 of the upper housing 70 and the upper end of the lower housing 51 are joined together by the bolts 84 (one being shown in FIG. 3) with the elastic seal member 78 disposed therebetween so that a hermetic seal is formed between the flange portion 73 and the upper end face of the lower housing 51. The elastic seal member 78 is elastically deformed or distorted within the annular groove 79 such that an elastic restoring force of the elastic seal member 78 acts in a direction to urge the flange portion 73 of the upper housing 70 and the lower housing 51 to move away from each other along the axis of the pinion shaft 24.

The terminal 74 is formed as an integral part of the housing body 71 and projects in a radial outward direction of the housing body 71. The terminal 74 includes a central current-carrying portion 74a and a cylindrical wall 74b disposed circumferentially around the current-carrying portion 74a.

With the magnetostrictive torque sensor 60 thus constructed, because the plastic housing body 71 and the metal flange portion 73 are structurally independent from each other, the plastic housing body 71 can be formed into a cylindrical shape having a substantially uniform thickness throughout an axial length thereof. This means that the amount of synthetic resin material used to form the plastic housing body 71 is substantially uniform throughout the axial length of the housing body 71, and the amount of thermal contraction occurring during the production of the plastic housing body 71 is substantially uniform throughout the axial length of the plastic housing body 71. The plastic housing body 71 is molded integrally with the coil bobbin 63 with the detection coils 65, 66 wound on the coil bobbin 63. By virtue of the substantially uniform thermal contraction throughout the axial length of the plastic housing body 71, a compressive force applied to the upper yoke 67 and a compressive force applied to the lower yoke 68 are substantially equal in magnitude and the upper and lower yokes 67, 78 have substantially the same magnetic permeability. This will ensure that the detection coils 65, 66 have substantially the same level of sensitivity. Additionally, because a first portion of the plastic housing body 71 corresponding in position to the upper detection coil 65 and a second portion of the plastic housing body 71 corresponding in position to the lower detection coil 66 contract in a radial inward direction of the housing body 71 by substantially the same amount, an air-gap between the magnetostrictive elements 61, 62 on the pinion shaft 24 and the coil bobbin 63 remains constant with respect to each of the detection coils 65, 66. This will insure highly accurate detection sensitivity of the magnetostrictive torque sensor 60.

The metal flange portion 73 is firmly connected to the axial end portion 71 of the plastic housing body 71 by the plastic fastener member 72. The plastic housing body 71 is molded integrally with the coil bobbin 63 having the detection coils 65, 66 wound thereon in a first or primary molding process, and the plastic fastener member 72 is molded integrally with the plastic housing body 71 and the metal flange portion 73 in a secondary molding process. With this arrangement, thermal contraction of the plastic fastener member occurring when the molded plastic fastener member 72 cools down and becomes solidified gives no direct effect on the performance of the detection coils 65, 66. The detection coils 85, 66 can thus retain their high detection sensitivity.

In the magnetostrictive torque sensor 60, the pinion shaft 24 provided with the magnetostrictive elements 61, 62 is rotatably supported by the lower housing 51 via the bearings 54, 55 at the longitudinally intermediate portion 24c and the output end portion 24a (lower end portion in FIG. 3) that are located below the metal flange portion 73 of the upper housing 70. With this arrangement, when the pinion shaft 24 undergoes expansion due to heat, the pinion shaft 24 will extend in a direction toward an input end side 24b (upper end side in FIG. 3) of the pinion shaft 24 with the longitudinally intermediate portion 24c being regarded as a start point of axial thermal expansion of the pinion shaft 24. In this instance, partly because the plastic housing body 71 has a larger linear expansion coefficient than the metal flange portion 73, and partly because an elastic restoring force of the elastic seal member 77 which acts in a direction to urge the plastic housing body 71 and the metal flange portion 73 to move away from each other along the axis of the pinion shaft 24, the plastic housing body 71 is allowed to move relative to the metal flange portion 73 in the same direction as the direction of thermal expansion of the pinion shaft 24. Thus, the detection coils 65, 66 are kept in correct alignment with the magnetostrictive elements 61, 62, respectively, which will insure high detection accuracy of the magnetostrictive torque sensor 60.

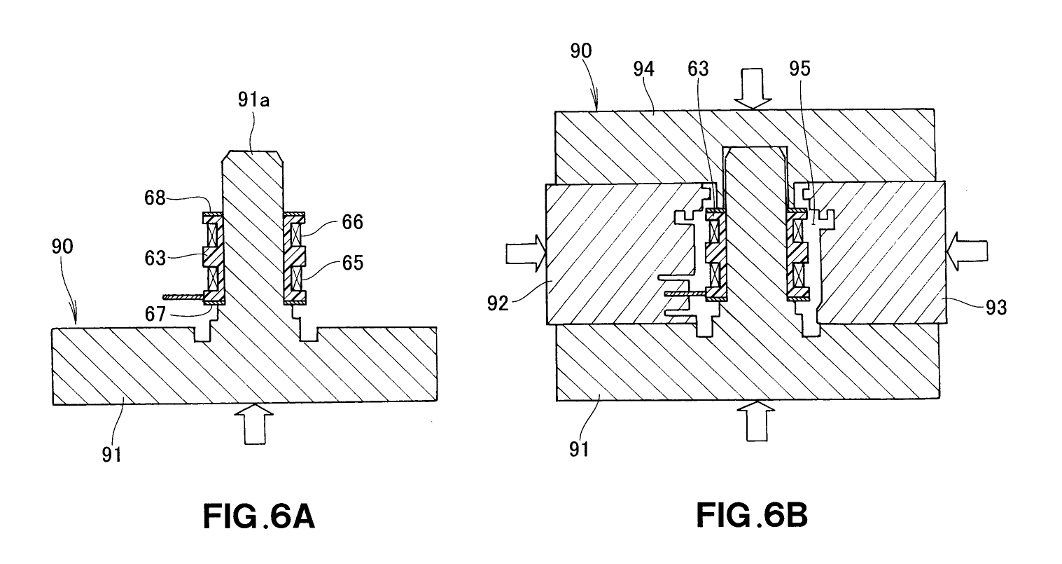

A method of manufacturing the magnetostrictive torque sensor 60 will be described below with reference to FIGS. 6A and 6B, FIGS. 7A and 7B, FIGS. 8A and 8B and FIG. 9.

As shown in FIG. 6A, a coil bobbin 63 having two detection coils 65, 66 wound thereon is set on a centering post 91a of a lower die member 90 of a first molding die assembly 90 with two yokes 67, 68 disposed on opposite end faces of the coil bobbin 63.

Then, as shown in FIG. 6B, a left side die member 92, a right side die member 93 and an upper die member 94 are moved relative to the lower die member 91 to thereby complete the first molding die assembly 90 such that a mold cavity 95, which is complementary in contour to a plastic housing body 71 to be produced, is defined within the first molding die assembly 90.

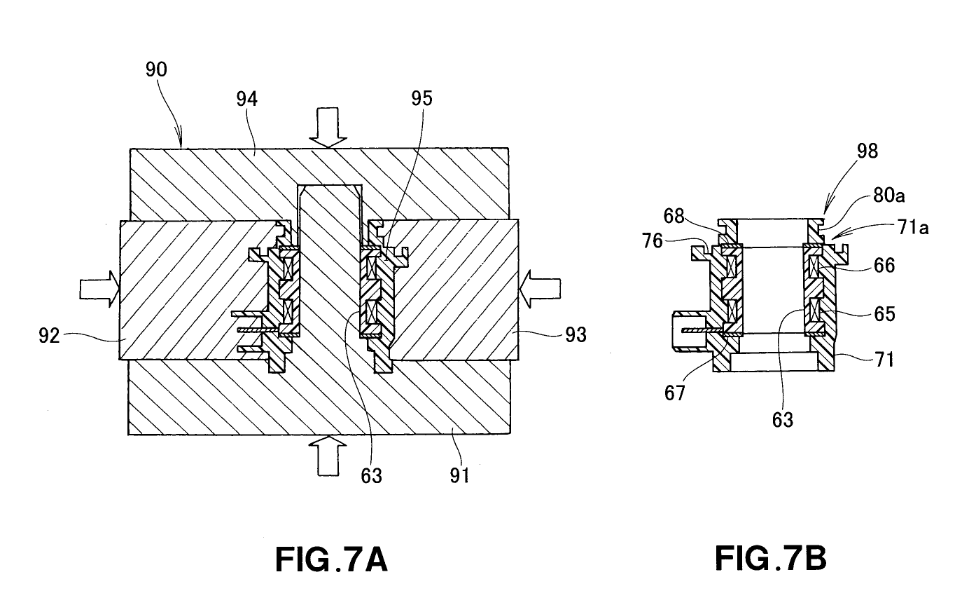

Subsequently, as shown in FIG. 7A, the mold cavity 95 formed within the first molding die assembly 90 is filled with a molten synthetic resin material. The synthetic resin material is allowed to cool down and becomes solidified.

Then, after solidification, a molded product 98 is removed from the first molding die assembly 78, as shown in FIG. 7B. The molded product 98 is composed of a plastic housing body 71 and a coil assembly including the coil bobbin 63, the detection coils 65, 66 and the yokes 67, 68 that are molded integrally with the plastic housing body 71 in an accurate concentric relation to a central axis of the plastic housing body 71. The plastic housing body 71 of the molded product 98 has an axial end portion 71a having a circumferential groove 80a and an annular groove 76.

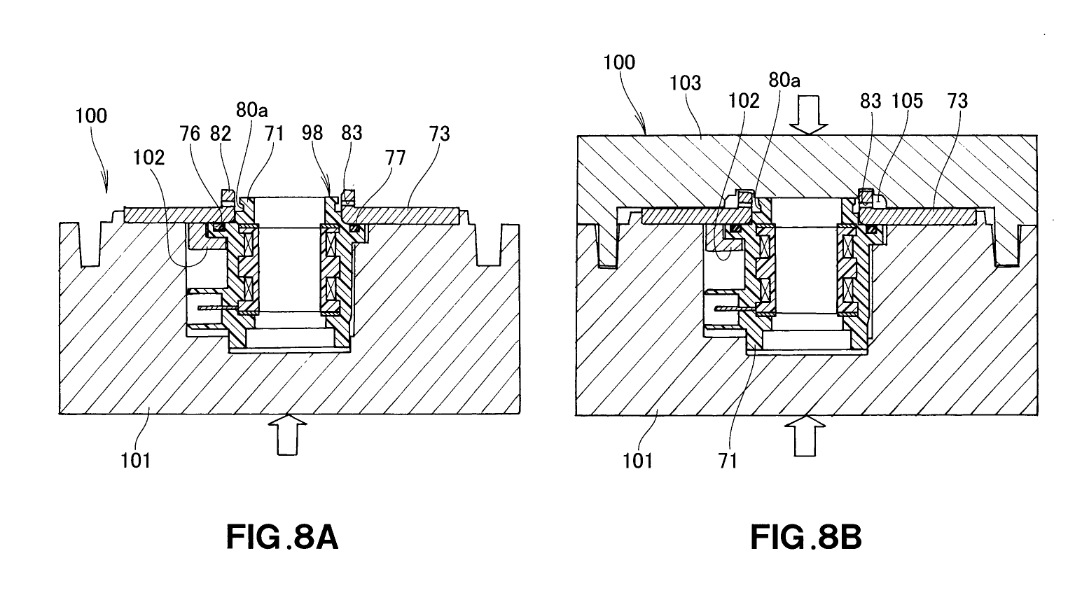

Subsequently, as shown in FIG. 8A, the molded product 98 is set on a lower die member 101 of a second molding die assembly 100, then an elastic seal member (O-ring) 77 is set in the annular groove 76 of the plastic housing body 71 and, thereafter, a metal flange portion 73 is placed on the axial end portion 71a (FIG. 7B) of the plastic housing body 71 with the elastic seal member (O-ring) 77 disposed therebetween. A slide die member 102 is disposed below the metal flange portion 73 for supporting the axial end portion 71a (FIG. 7B) from below.

Then, as shown in FIG. 8B, an upper die member 103 of the second molding die assembly 100 is lowered toward the lower die member 101 to complete the second molding die assembly 100 such that a mold cavity 105, which is complementary in contour to a plastic fastener member 72 to be produced, is formed within the second molding die assembly 100. In this instance, through-holes 83 formed in a central boss 82 of the metal flange portion 73 connected at one end with the circumferential groove 80a of the axial end portion of the plastic housing body 71, and the elastic seal member 77 is disposed between the axial end portion of the plastic housing body 71 and the metal flange portion 73 in an elastically disported condition such that an elastic restoring force of the elastic seal member 77 acts in a direction to urge the plastic housing body 71 and the metal flange portion 73 to move away from each other along the central axis of the housing body 71.

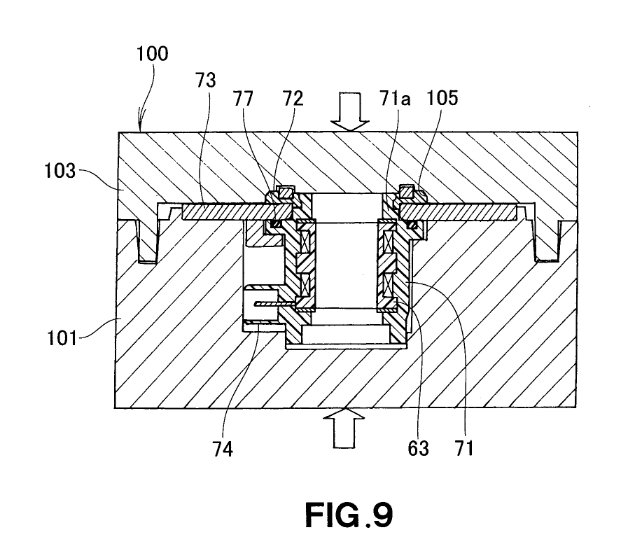

Subsequently, as shown in FIG. 9, the mold cavity 105 of the second molding die assembly 100 is filled with a molten synthetic resin material. The synthetic resin material is allowed to cool down and becomes solidified. After solidification, a plastic fastener member 72 is formed, which connects the metal flange portion 73 to the axial end portion 71a of the plastic housing body 71.

Since the coil assembly composed of the coil bobbin 63, the detection coils 65, 66, and the yokes 67, 68 is integrally molded with the plastic housing body 71 in a first or primary molding process which is achieved before the metal flange portion 73 is connected to the axial end portion of the plastic housing body 71, the housing body 71 can be formed into a generally cylindrical shape having a substantially uniform thickness throughout an axial length thereof. When such cylindrical plastic housing body 71 having a uniform thickness undergoes thermal expansion, the amount of thermal expansion is substantially uniform throughout the axial length of the housing body 71. This will insure high detection sensitivity of the detection coils 65, 66. Additionally, because the metal flange portion 73 is firmly connected to the axial end portion of the plastic fastener member 72 formed by molding during a secondary molding process, thermal contraction of the molded plastic fastener member 72 gives no direct effect on the performance of the detection coils 65, 66. The magnetostrictive torque sensor 60 can achieve toque detection with high accuracy.

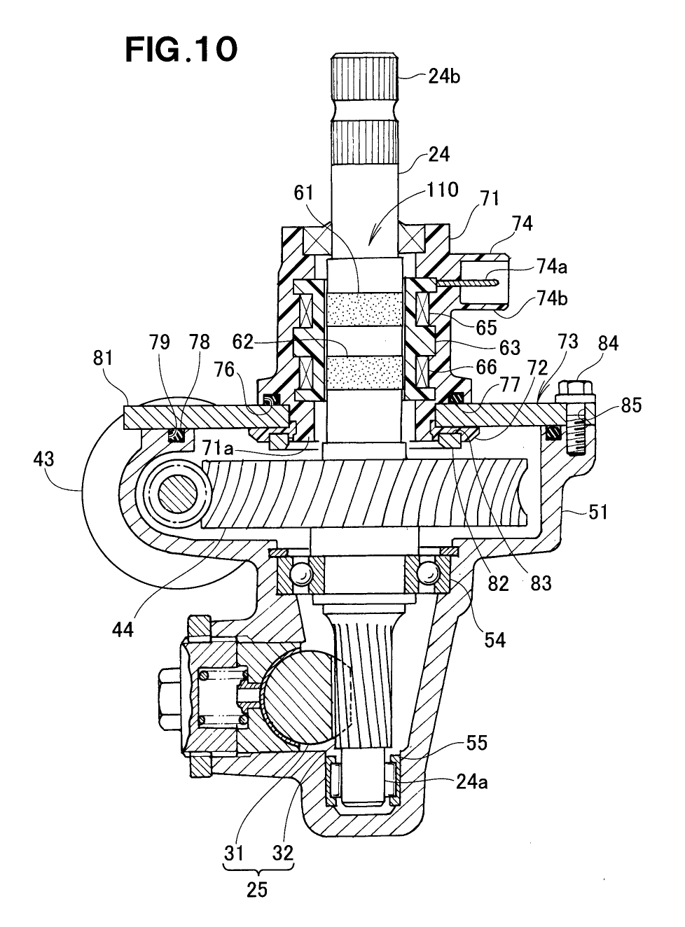

FIG. 10 shows in cross section a magnetostrictive torque sensor 110 according to a second embodiment of the present invention. The magnetostrictive torque sensor 110 is structurally and functionally the same as the magnetostrictive torque sensor 60 of the first embodiment shown in FIG. 3 with the exception that a coil assembly has no yoke disposed on opposite end faces of a coil bobbin 63. A further description of the torque sensor 110 can therefore be omitted.

Although in the illustrated embodiments, the magnetostrictive torque sensors 60, 110 are used in an electric power steering apparatus 10 of a vehicle, the present invention can be applied to any other apparatus in which detection of a torque is a major requirement.

Obviously, various minor changes and modifications of the present invention are possible in light of the above teaching. It is therefore to be understood that within the scope of the appended claims the invention may be practiced otherwise than as specifically described.

What is claimed is:

1. A magnetostrictive torque sensor comprising:
a rotary shaft;
a magnetostrictive element provided on the rotary shaft;
a single coil bobbin arranged to face the magnetostrictive element;
a plurality of detection coils wound on the coil bobbin and spaced apart in an axial direction of the coil bobbin for detecting a change in magnetic characteristic of the magnetostrictive element; and
a housing configured to house the magnetostrictive element, the coil bobbin and the detection coils,
wherein the housing includes:
a plastic housing body having a generally cylindrical shape and molded integrally with the coil bobbin having the detection coils wound thereon,
a metal flange portion disposed on an axial end portion of the generally cylindrical plastic housing body, and
a plastic fastener member firmly connecting the metal flange portion to the axial end portion of the plastic housing body.

2. The magnetostrictive torque sensor according to claim 1, wherein the axial end portion of the plastic housing body has a cylindrical surface and a circumferential groove formed in the cylindrical surface, the metal flange portion has a central boss fitted with the cylindrical surface of the axial end portion of the plastic housing body and a plurality of through-holes extending radially through the central boss, the through-holes having one end connected with the circumferential groove of the axial end portion of the plastic housing body, and the plastic fastener member has a first ring-shaped portion disposed on a radial outer side of the central boss of the metal flange portion, a second ring-shaped portion disposed in the circumferential groove of the axial end portion of the plastic housing body and a plurality of radial arms extending between the first and second ring-shaped portions and disposed in respective ones of the through-holes of the metal flange portion.

3. The magnetostrictive torque sensor according to claim 2, wherein the plastic fastener member is molded integrally with the plastic housing body and the metal flange portion.

4. The magnetostrictive torque sensor according to claim 1, further comprising an elastic member disposed between the axial end portion of the plastic housing body and the metal flange portion in an elastically distorted condition such that an elastic restoring force of the elastic member acts in a direction to urge the plastic housing body and the metal flange portion to move away from each other along an axis of the rotary shaft.

5. The magnetostrictive torque sensor according to claim 4, wherein the axial end portion of the plastic housing body has an end surface disposed in abutting contact with a surface of the metal flange portion and an annular groove formed in the end surface, and the elastic member is an O-ring disposed in the annular groove of the plastic housing body.

6. A method of manufacturing a magnetostrictive torque sensor including a housing having a plastic housing body and a metal flange portion firmly connected to an end portion of the plastic housing body by a plastic fastener member with a coil bobbin firmly held within the plastic housing body with a plurality of detection coils wound on the coil bobbin, the method comprising the steps of:
providing a single coil bobbin having a plurality of detection coils wound thereon, and a metal flange portion;
setting the coil bobbin in a first molding die assembly such that a mold cavity which is complementary in contour to the plastic housing body of the housing to be produced is formed within the first molding die assembly;
filling the mold cavity with a molten synthetic resin material to thereby form a plastic housing body having the coil bobbin firmly held therein with the detection coils wound on the coil bobbin;
setting the plastic housing body and the metal flange portion in a second molding die assembly such that a mold cavity which is complementary in contour to the plastic fastener member of the housing to be produced is formed within the second molding die assembly; and
filling the mold cavity of the second molding die assembly with a molten synthetic resin material to thereby obtain a housing having the metal flange portion firmly connected to an axial end portion of the plastic housing body by a molded plastic fastener member.

7. The method according to claim 6, wherein the setting the plastic housing body and the metal flange portion in the second molding die assembly is carried out while an elastic member is held between the axial end portion of the plastic housing body and the metal flange portion in an elastically distorted condition such that an elastic restoring force of the elastic member acts in a direction to urge the plastic housing body and the metal flange portion to move away from each other along an axis of the plastic housing body.
